(19) United States
(12) Patent Application Publication
(10) Pub. No.: US 2014/0346936 A1
(43) Pub. Date: Nov. 27, 2014

(54) PROTECTION COVER

(71) Applicant: Samsung Electronics Co., Ltd., Gyeonggi-do (KR)

(72) Inventors: Hyun-Jung Kim, Seoul (KR); Heung-Sik Shin, Jeollabuk-do (KR); Cheol-Ho Cheong, Seoul (KR); Bo-Hyun Yu, Gyeonggi-do (KR); Chul-Hwan Lee, Seoul (KR)

(73) Assignee: Samsung Electronics Co., Ltd., Gyeonggi-do (KR)

(21) Appl. No.: 14/248,196

(22) Filed: Apr. 8, 2014

(30) Foreign Application Priority Data
May 27, 2013 (KR) 10-2013-0059552

(51) Int. Cl. H05K 5/02

(52) U.S. Cl. CPC H05K 5/0247
USPC 312/223.1

(57) ABSTRACT

Disclosed is a protection cover for protecting an electronic device, including: a base; and a conductor formed at least a portion of the base. In some embodiments, the conductor may be located to be spaced apart from a display unit of the electronic device. In some embodiments, the base may be formed of a transparent or semitransparent flexible film or plastic. In some embodiments, the conductor is applied, coupled, or attached to the base. In some embodiments, the base has at least one convex part, and the conductor may be formed at a portion of the convex part facing the electronic device.

### CROSS-REFERENCE TO RELATED APPLICATION(S) AND CLAIM OF PRIORITY

The present application is related to and claims the priority under 35 U.S.C. §119(a) to Korean Application Serial No. 10-2013-0059552, which was filed in the Korean Intellectual Property Office on May 27, 2013, the entire content of which is hereby incorporated by reference.

### TECHNICAL FIELD

The present disclosure relates to a protection cover, and more particularly, to a protection cover for protecting electrical devices and an external case including the same.

### BACKGROUND

In recent years, electronic devices such as a mobile phone, an MP3 player, a Portable Multimedia Player (PMP), and an electronic book terminal are provided to users. Users can use various contents while carrying the electronic devices.

The portable electronic devices can perform wireless communications with others while users are carrying the portable electronic devices. The portable electronic devices include a display unit, an antenna unit, an input/output unit, and a data transmitting/receiving unit.

Further, multimedia technologies and display technologies have rapidly advanced in recent years. A resolution of a display unit of a portable electronic device has been enhanced, and since a touch screen is provided in the display unit, users can manipulate the electronic device through a touch of the display unit of the electronic device with a finger or a stylus pen.

Touch type display units are classified into a resistive overlay type, a capacitive overlay type, an optical type, and a surface acoustic wave type. In particular, the resistive overlay type and the capacitive overlay type are the most widely used types in portable electronic devices. The resistive overlay type detects a touched position via an electrode that is short-circuited by a pressure applied to the display unit. The capacitive overlay type detects a touched position as a change in capacitance between electrodes that is detected when a finger contacts the display unit.

The capacitive overlay type display unit has a high accuracy for touch detection, and can be accurately controlled by using a touch, but since the capacitive overlay type display unit detects a change in an electric current through a dielectric such as a finger, the capacitive overlay type display unit cannot perform the touch manipulation through an object (a glove, a thermal glove, or a rubber glove) other than a finger. For example, when a user wears a thermal glove in cold winter, wears a rubber glove to do housework, or manipulates the electronic device for work while wearing a glove formed of a fiber material, the user must take off the glove before touching a front surface of the display unit with a finger to manipulate the electronic device.

As a result, an apparatus which can perform a touch manipulation on a display unit while a user wears a glove is required.

### SUMMARY

To address the above-discussed deficiencies of the prior art, an aspect of the present disclosure is to provide a protection cover having a conductor and disposed on a front surface of an electronic device, by which a touch input is performed on the protection cover in a situation in which an input through a finger or a stylus pen is impossible, and a user can perform a touch input while wearing a thermal glove, a household glove, and another glove for work so that the usability of products can be improved.

Further, another aspect of the present disclosure is to provide an external case for protecting an electronic device which includes a protection cover having a conductor to perform a touch input through the protection cover of the external case in a situation in which a user cannot perform a touch input so that the usability of the external case can be improved.

In accordance with another aspect of the present disclosure, there is provided a protection cover for protecting an electronic device, including: a base; and a conductor that farms at least a portion of the base.

In accordance with another aspect of the present disclosure, there is provided an external case for protecting an electronic device, including: a front cover having a protection cover and a rear cover connected to the front cover and disposed on a rear surface of the electronic device. The protection cover comprises a base and a conductor that forms at least a portion of the base.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is an exploded perspective view showing a configuration of a protection cover provided in an electronic device according to embodiments of the present disclosure;

FIG. 2 is a perspective view showing an operation state of the protection cover according to embodiments of the present disclosure;

FIG. 3 is a perspective view showing a state in which convex parts are provided in the protection cover according to embodiments of the present disclosure;

FIG. 4 is a side sectional view showing an operation state of the convex parts of FIG. 3 according to embodiments of the present disclosure;

FIG. 5 is a perspective view showing a state in which convex parts are provided in the protection cover according to embodiments of the present disclosure;

FIG. 6 is a side sectional view showing an operation state of the convex parts of FIG. 5 according to embodiments of the present disclosure;

FIG. 7 is a perspective view showing a state in which convex parts are provided in the protection cover according embodiments of the present disclosure;

FIG. 8 is a side sectional view showing an operation state of the convex parts of FIG. 7 according to embodiments of the present disclosure;

FIG. 9 is a perspective view showing supports formed in the protection cover according to embodiments of the present disclosure;

FIG. 10 is a perspective view showing a connection part of the protection cover according to embodiments of the present disclosure;

FIG. 11 is a perspective view showing a state in which the connection part of the protection cover is provided on a rear surface of an electronic device according to embodiments of the present disclosure;

FIG. 12 is a perspective view showing a state in which the connection part of the protection cover is provided on a front surface of the electronic device according to embodiments of the present disclosure;

FIG. 13 is an exploded perspective view showing a configuration of an external case including a protection cover according to embodiments of the present disclosure;

FIG. 14 is a side sectional view showing a state in which the protection cover is provided in the external case according to embodiments of the present disclosure; and

FIG. 15 is a perspective view showing the protection cover configured to be attached to and detached from the external case according to embodiments of the present disclosure.

### DETAILED DESCRIPTION

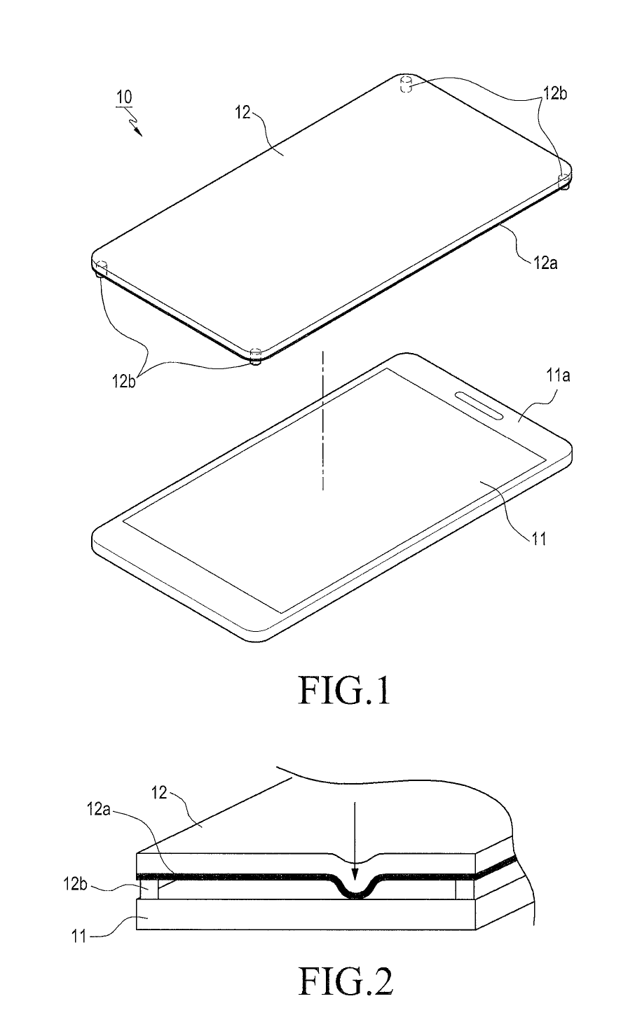

FIGS. 1 through 15, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged electronic device.

A protection cover 10 (see FIG. 1) provided in an electronic device 11a (see FIG. 1) according to certain embodiments of the present disclosure will be described with reference to the accompanying drawings. Applications of the electronic device include all information communication devices, multimedia devices, and application devices thereof such as portable multimedia players (PMPs), MP3 players, navigation devices, gaming devices, notebooks, net books, advertising panels, TVs, digital broadcasting players, personal digital assistants (PDAs), and smart phones, including all mobile communication terminals operated based on communication protocols corresponding to various communication systems.

In more detail, a configuration of the protection cover 10 is described with reference to FIGS. 1 and 2. FIG. 1 is an exploded perspective view showing the configuration of the protection cover according to embodiments of the present disclosure, and FIG. 2 is a perspective view showing an operation of the protection cover according to embodiments of the present disclosure.

Referring to the drawings, the protection cover 10 includes a base 12 and a conductor 12a formed on one surface of the base 12. The conductor 12a forms at least a portion of the base 12. The protection cover 10 is located on a front surface of a display unit 11 of the electronic device 11a, and is located to be spaced apart from the display unit 11 provided in the electronic device 11a.

The base 12 is formed of transparent or semitransparent flexible films or plastics. The present embodiment exemplifies that the base 12 is formed of a transparent flexible film or plastic, but is not limited thereto. That is, any configuration which can be pressed by a touch of a user can be applied to various modified examples as the base 12.

The conductor 12a located on one surface of the base 12 is applied, coupled, or attached to the base 12. The conductor 12a acts as a passage for current movement.

The display unit 11 of FIG. 1 is formed as a capacitive overlay type touch screen. In a brief description of the electronic device 11a including the capacitive overlay type touch screen, the capacitive overlay type touch screen detects a position touched on the display unit by using a change in a capacitance between a sensor electrode (not shown) and a driving electrode (not shown). For example, the capacitive overlay type touch screen detects a change in a capacitance of a specific point by sequentially measuring capacitances of a plurality of crossing points formed by a plurality of sensor electrodes arranged along a horizontal axis direction and a plurality of driving electrodes arranged along a vertical axis direction.

Referring to FIG. 2, in a detailed description of a spaced position of the conductor 12a and the display unit 11, one or more spacing portions 12b is provided in the protection cover 10 to space the conductor 12a apart from the display unit 11. The spacing portions 12b space the base 12 having the conductor 21a apart from the display unit 11 so that the conductor 21a formed on one surface of the base 12 does not touch the display unit 11 when the base 12 is not touched.

When an external force is applied to a portion of the base 12 of the protection cover 10, the portion of the base 12, to which the external force is applied, is deformed as shown in FIG. 2 due to a flexibility of the base 12. The conductor 12a formed on one surface of the base 12 touches the display unit 11 due to the deformation of the base 12. The capacitance of the crossing points formed by the sensor electrodes and the driving electrodes is changed so that the touched point can be detected when the conductor 12a touches the capacitive overlay type display unit.

The spacing portions 12b are formed of a conductive material or a nonconductive material, and are formed with any one of a frame, a cover, an adhesive, an adhesive tape, a cylindrical boss, a hemispherical boss, a domed boss, a segment protrusion, and a grid protrusion. The spacing portions 12b are formed of the disclosed components as well as other types of components.

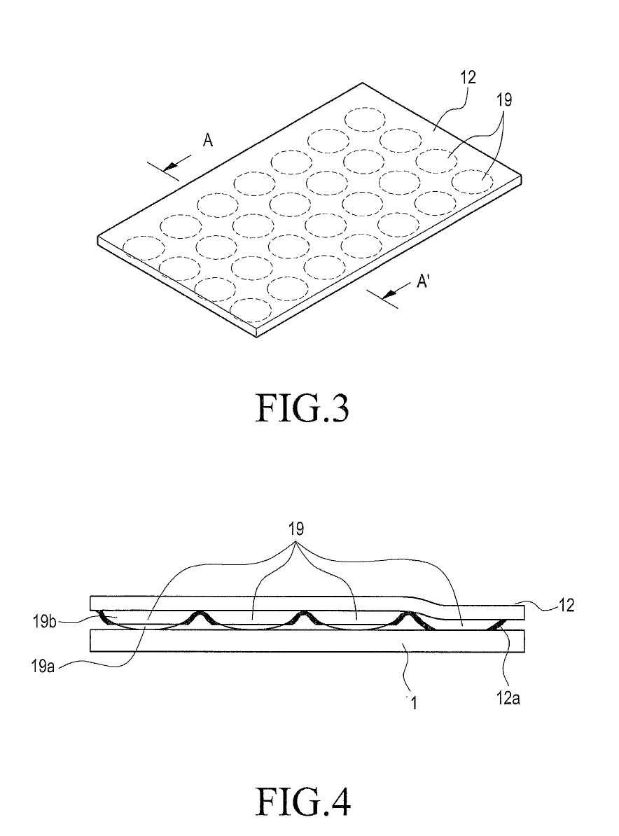

In another example, referring to FIGS. 3 and 4, one or more convex parts 19 are formed in the protection cover 10 to space the base 12 apart from the display unit 11, and the conductor 12a forms at least a portion of the convex parts 19 facing the display unit 11 of the electronic device 11a.

The convex parts 19 are formed of any one of an embossing boss, a cylindrical boss, a hemispherical boss, a conical boss, and a tetragonal boss. Of course, the convex parts 19 can be formed of other convex bosses in addition to the above-described bosses.

The convex parts 19 are described in more detail with reference to the following drawings. FIG. 3 is a perspective view showing the convex parts applied to the protection cover according to embodiments of the present disclosure, and FIG. 4 is a side sectional view showing an operation state of the convex parts along line A-A′ of FIG. 3.

Referring to FIGS. 3 and 4, one or more convex parts 19 are provided on a lower surface of the base 12 constituting the protection cover 10, and the convex parts 19 include contacting portions 19a contacting the display unit 11. Of course, the contacting portions 19a can be formed of a nonconductive material to space the base 12 apart from the display unit 11. Further, the conductor 12a is formed at the remaining portions 19b other than the contacting portions 19a such that an external force is applied to the base 12 and the contacting portions 19a is deformed so that touch inputs are possible.

As shown in FIG. 4, the contacting portions 19a of the convex parts 19 are formed of a nonconductive material such that a touch input is impossible, and the conductor 12a is formed at the remaining portions 19b other than the contacting portions 19a of the convex parts 19 such that a touch input is possible. Accordingly, the contacting portions 19a of the convex parts 19 are formed of a nonconductive material, and a touch input is not generated when the contacting portions 19a contact an upper surface of the display unit 11.

In other words, since the remaining portions 19b formed of the conductor 12a are spaced apart from the display unit 11 by the contacting portions 19a formed of a nonconductive material before a user touches the base 12, a touch input is not generated in the display unit. In this state, the conductor 12a formed at the remaining portions 19b of the convex parts 19 contacts the display unit 11 so that a touch input occurs while the base 12 and the contacting portions 19a of the convex parts 19 are deformed at the same time when a user touches the protection cover 10.

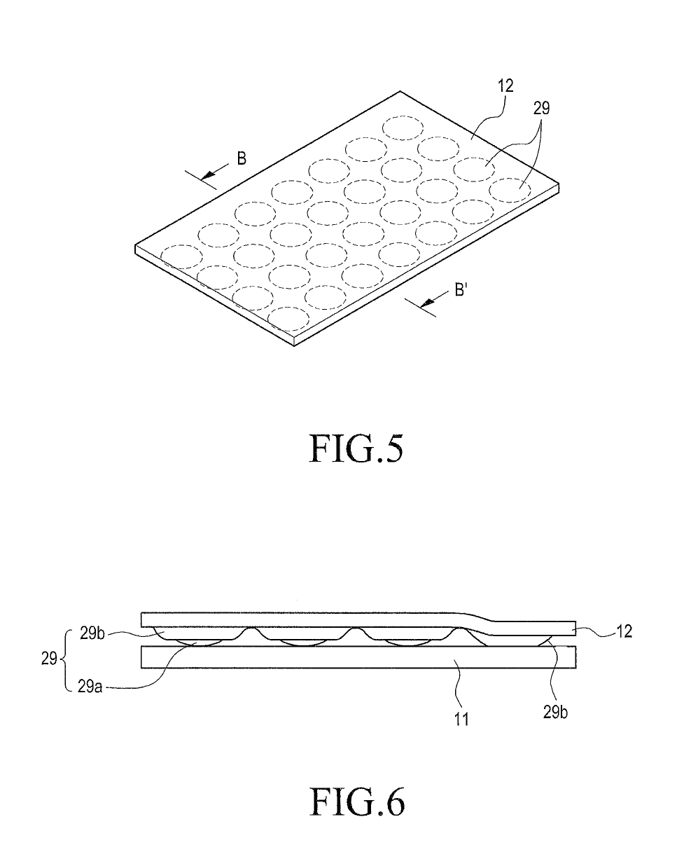

Further, another example of the convex parts will be described in more detail below with reference to the following drawings. FIG. 5 is a perspective view showing another example of the convex parts according to embodiments of the present disclosure, and FIG. 6 is a side sectional view showing an operation of the convex parts along line B-B′ of FIG. 5.

First, referring to FIGS. 5 and 6, one or more convex parts 29 are provided on the lower surface of the base 12, and contacting portions 29a contacting the display unit 11 are provided in the convex parts 29. The contacting portions 29a of the convex parts 29 are formed of a nonconductive material, and the remaining portions 29b other than the contacting portions 29a of the convex parts 29 are formed of a conductive material. That is, the remaining portions 29b of the convex parts 29 are formed of a conductive material, and the conductive material is not formed on outer surfaces of the remaining portions 29b. Thus, as shown in FIG. 6, the contacting portions 29a of the convex parts 29 formed of a nonconductive material contact the upper surface of the display unit 11, space the base 12 apart from the display unit 11, and serve not to generate the touch inputs with the display unit 11 and the conductor. Then, the base 12 and the contacting portions 29a of the convex parts 29 are pressed while being deformed at the same time, and the remaining portions 29b of the convex parts 29 formed of a conductive material contact the display unit 11 so that a touch input is performed, when a user touches the base 12.

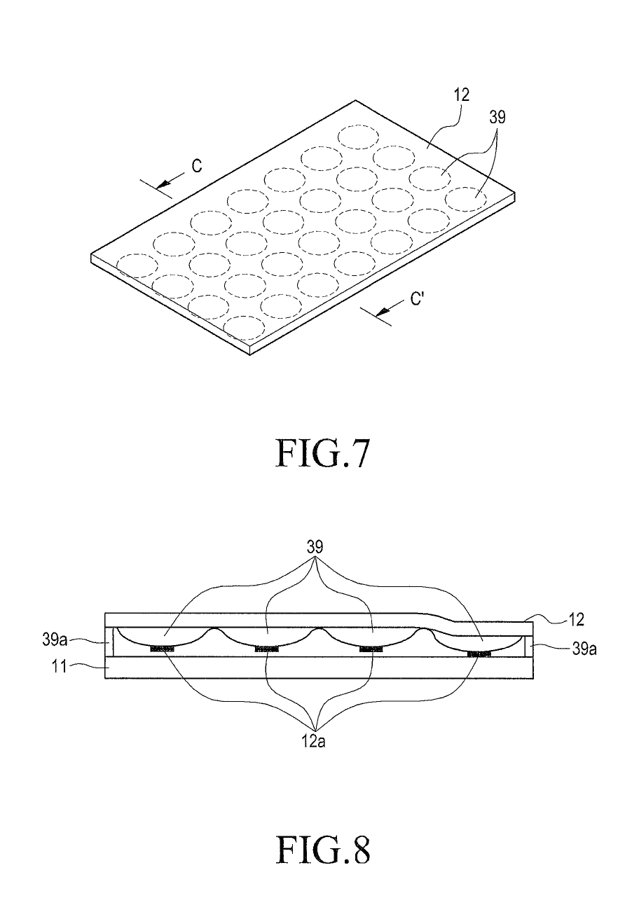

Further, another example of the convex parts will be described in more detail below with reference to the following drawings. FIG. 7 is a perspective view showing another example of the convex parts according to embodiments of the present disclosure, and FIG. 8 is a side sectional view showing an operation of the convex parts along line C-C′ of FIG. 7.

First, as shown in FIGS. 7 and 8, the base 12 and one or more convex parts 39 disposed on the lower surface of the base 12 are provided in the protection cover 10, and one or more separation portions 39a are formed such that the convex parts 39 and the display unit 11 are spaced apart from each other.

That is, the separation portions 39a space the convex parts 39 apart from the display unit 11 such that the convex parts 39 and the display unit 11 do not contact each other when the user does not touch the base 12. Accordingly, a touch input does not occur in the display unit 11.

In this state, as shown in FIG. 8, when the user touches and presses the base 12, the conductors 12a are formed so that at least some portion of the base 12 contacts the display unit 11 as the base 12 is pressed and the touch inputs are performed by the conductors 12a.

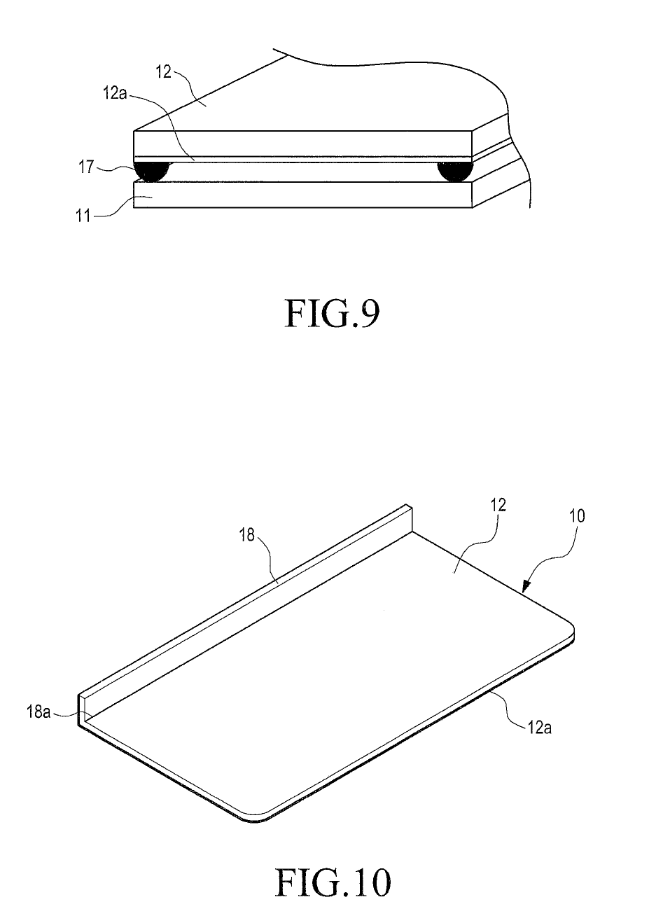

Further, one or more supports 17 are formed in the base 12 to space the base 12 apart from the display unit 11. Of course, the supports 17 can be mounted or attached to a front surface of the electronic device 11a. The supports 17 formed in the base 12 are described in detail with regard to FIG. 9.

FIG. 9 is a perspective view showing the supports 17 according to embodiments of the present disclosure. As shown in FIG. 9, the supports 17 space the display unit 11 apart from the base 12, and are formed with a magnet to be attached to the front surface of the electronic device 11a. In the present embodiment, a magnet is exemplified as the supports 17 but the present disclosure is not limited thereto. Other configurations which can space the base 12 apart from the display unit 11 or can be mounted to the display unit 11 can be applied to the supports 17. For example, supports formed of a flexible nonconductive material can be applied to the supports 17.

Further, as shown in FIGS. 10 to 12, the protection cover 10 includes a connection part 18 connected to the protection cover 10 and rotated through a hinge 18a. The connection part 18 is disposed on at least one lateral surface of the electronic device 11a. The connection part 18 will be described in detail below.

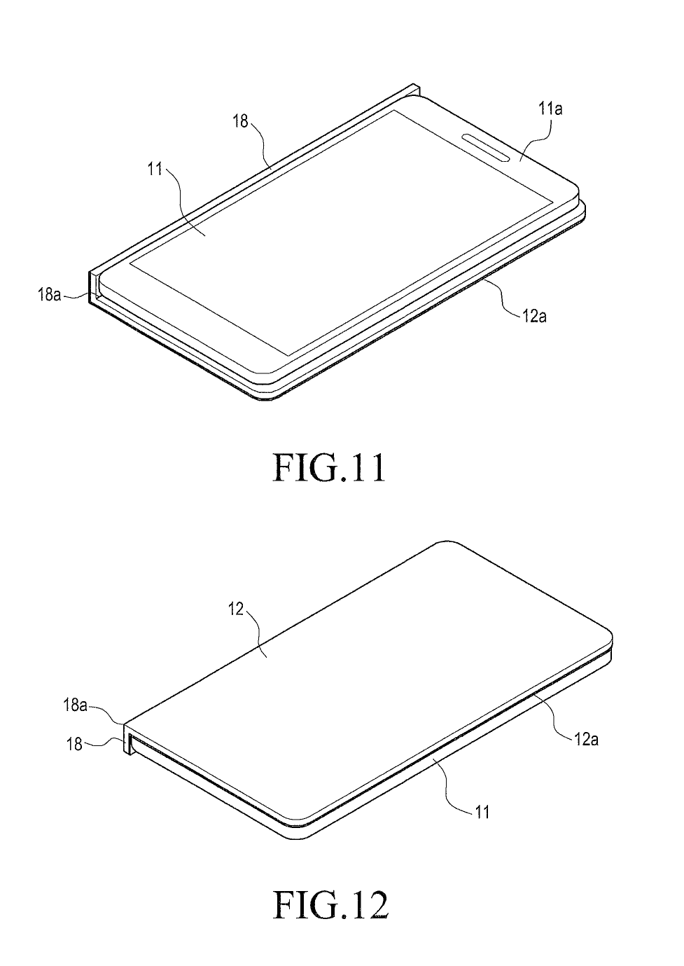

FIG. 10 is a perspective view showing the connection part of the protection cover according to embodiments of the present disclosure. FIG. 11 is a perspective view showing a state in which the connection part of the protection cover is provided on a rear surface of the electronic device 11a according to embodiments of the present disclosure. FIG. 12 is a perspective view showing a state in which the connection part of the protection cover is provided on the front surface of the electronic device according to embodiments of the present disclosure.

First, referring to FIG. 10, the connection part 18 is provided on a lateral surface of the protection cover 10 such that the protection cover 10 can cover or open a front surface of the display unit 11 of the electronic device 11a by using rotation of the hinge 18a. A magnet (not shown) can be provided in the connection part 18 such that the protection cover 10 can be mounted to the electronic device 11a by a magnetic force.

As shown in FIGS. 10 and 11, the connection part 18 provided on the lateral surface of the protection cover 10 is rotated by the hinge 18a when the protection cover 10 is not used. Then, the protection cover 10 and the connection part 18 are disposed in an L-shape, and the electronic device 11a is mounted to the protection cover 10 and the connection part 18. The protection cover 10 is mounted to the electronic device 11a by a magnetic force of a magnet (not shown) of the connection part 18.

As shown in FIG. 11, the electronic device 11a is mounted to an upper side of the protection cover 10 or on the lateral surface of the connection part 18, and then the front surface of the electronic device 11a is opened. That is, the display unit 11 of the electronic device 11a is opened.

As shown in FIG. 12, the connection part 18 formed on the lateral surface of the protection cover 10 is rotated by the hinge 18a when the protection cover 10 is used. Then, the protection cover 10 and the connection part 18 are disposed in a “┐” shape, and the protection cover 10 and the connection part 18 are mounted to the electronic device 11a while covering the front surface of the display unit 11.

The protection cover 10 and the connection part 18 are mounted to the front surface of the electronic device 11a by a magnetic force of the magnet provided in the connection part 18. In this state, the protection cover 10 is pressed and the conductor 12a contacts the display unit 11 of the electronic device 11a at the same time so that a touch input is performed even if a user touches the protection cover 10 while wearing a glove.

Further, the material of the conductor 12a is one of graphene polymer, gold (Au), silver (Ag), copper (Cu), indium oxide (In₂0₃), tin oxide (SnO₂), zinc oxide (ZnO), T0 (In₂O₃:Sn), FT0 (SnO₂:F), GZ0 (ZnO:Ga), AZ0 (ZnO:Al), conducting polymer (PEDOT; Poly(3,4-Ethylenedioxythiophene)), and metal nanowires Only some of the disclosed materials of the conductor can be applied within a range which does not derive from transparency of the protection cover.

In various embodiments of the present disclosure, the conductor 12a (see FIG. 1) is mounted to the protection cover 10 (see FIG. 1) so that the display unit 11 (see FIG. 1) of the electronic device 11a (see FIG. 1) is touched through the protection cover 10 and a touch input is performed when the protection cover 10 is pressed and touched in a state in which an input by a finger or a stylus pen is impossible.

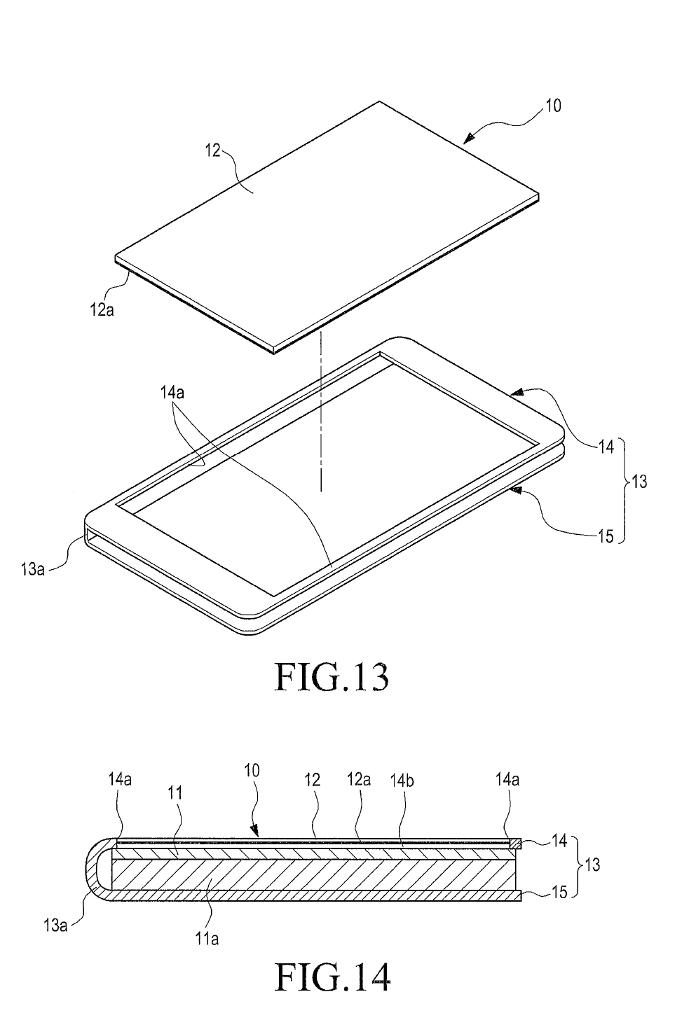

Referring to FIGS. 13 to 15, an external case including the protection cover is described. In a description of the external case 13 including the protection cover 10 of FIGS. 13 to 15, a description of the same configurations as those of the protection cover 10 of FIGS. 1 to 12 is omitted, and different points will be described. The protection cover 10 of FIGS. 13 to 15 is provided in the external case 13 for protecting the electronic device 11a as compared with the protection cover 10 of FIGS. 1 to 12.

FIG. 13 is an exploded perspective view showing the external case including the protection cover according to embodiments of the present disclosure. FIG. 14 is a side sectional view showing a state in which the protection cover is provided in the external case according to embodiments of the present disclosure.

First, as shown in FIG. 13, the external case 13 has front and rear covers 14 and 15. The front cover 14 includes the protection cover 10 and is located on the front surface of the electronic device 11a, The rear cover 15 is connected to the front cover 14 and is located on a rear surface of the electronic device 11a.

Referring to FIG. 14, the protection cover 10 includes the base 12 and the conductor 12a formed on one surface of the base 12. The conductor 12a, which will be described below, is formed in the base 12, and is located on the front surface of the electronic device 11a. The conductor 12a forms at least a portion of the base 12. That is, the conductor 12a can be located on the front surface of the display unit 11 of the electronic device 11a and can be located to be spaced apart from the display unit 11 of the electronic device 11a.

As shown in FIGS. 13 and 14, the front cover 14 of the external case 13 is connected to the rear cover 15 by a cover connector 13a, opens and closes the front surface of the electronic device 11a while being rotated, and protects the front surface of the electronic device 11a. Further, the rear cover 15 is mounted on the rear surface of the electronic device 11a and can protect a rear case (not shown) of the electronic device 11a. Furthermore, the rear cover 15 is formed with a battery cover unit (not shown) of the electronic device 11a. That is, the rear cover 15 protects a battery pack (not shown) mounted on the rear surface of the electronic device 11a (shown in FIG. 3) when the rear cover 15 is formed with the battery cover unit.

The protection cover 10 is formed of transparent or semitransparent flexible films or plastics. Supports 14a, for spacing the front surface of the electronic device 11a apart from the protection cover 10 and supporting an installation of the protection cover 10, are provided in the front cover 14. The supports 14a are formed with support frames, and the support frames are exemplified as the supports 14a in the present embodiment, but the present disclosure is not limited thereto. Any configuration which can space the front surface of the electronic device 11a apart from the protection cover 10 can be applied to the supports 14a in various embodiments.

As shown in FIG. 14, the protection cover 10 is installed in the supports 14a and a space 14b is provided in the supports 14a such that the protection cover is spaced apart from the front surface of the electronic device 11a. The rear cover 15 is coupled to the rear surface of the electronic device 11a. The space 14b spaces the conductor 12a apart from the display unit 11 of the electronic device 11a in the front cover 14 so that the space 14b prevents the conductor 12a of the protection cover 10 from touching the front surface of the electronic device 11a when a user does not touch the protection cover 10. Further, the conductor 12a contacts the display unit 11 of the electronic device 11a so that a touch input can be performed when a user touches the protection cover 10. Accordingly, a touch input of the electronic device 11a or a touch input malfunction can be prevented.

Further, one or more supports 17 (see FIG. 9) are formed in the protection cover 10 of FIGS. 13 to 15 to space the protection cover 10 apart from the display unit 11. The supports 17 can be mounted or attached to a minimum area (for example, a bezel portion) of the front surface of the electronic device 11a. Since the supports 17 formed in the protection cover 10 have been already described and a description thereof will be omitted.

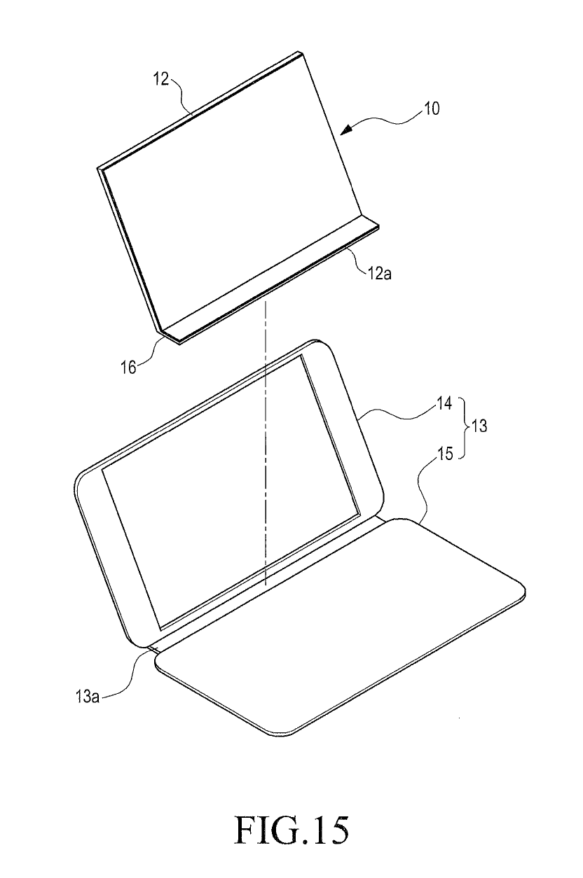

Referring to the FIG. 15, a detachable protection cover 10 of the external case 13 is described. As shown in FIG. 15, one or more attaching/detaching portions 16 are provided in the protection cover 10 such that the protection cover 10 can be attached to or detached from the external case 13 as the protection cover 10 is used.

The attaching/detaching portions 16 are formed of one or more of a connector, a snap fastener, a zipper, a latch, a Velcro, a loop, a hook, and a hinge. Other attaching/detaching configurations in addition to the above-described attaching/detaching configurations can be applied to the attaching/detaching portions 16.

In this way, when the protection cover 10 is used, the front cover 14 of the external case 13 is opened, and the protection cover 10 is attached to an inner side of the external case 13 by using the attaching/detaching portions 16. In this state, the electronic device 11a is mounted to the inner side of the external case 13. Further, when the protection cover 10 is not used, the protection cover 10 mounted to the inner side of the external case 13 is detached from the external case 13 by using the attaching/detaching portions 16, and the electronic device 11a is coupled to the detached external case 13 at the same time.

Thus, in certain embodiments of the present disclosure, the conductor 12a (see FIGS. 1 and 13) is formed in the protection cover 10 (see FIGS. 1 and 13) so that a touch input can be performed in a situation in which an input by a finger or a stylus pen is impossible, and the external case can be attached to and detached from the protection cover as the protection cover to which the conductor is mounted is used so that the usability of the protection cover can be improved.

Further, the protection cover 10 does not form the conductor 12a, but the entire protection cover 10 can be formed of a conductive protection cover. That is, the conductive protection cover, the entire portions of which are formed of the conductor, is formed on the front surface of the electronic device or in the external case so that the protection cover 10 can be pressed and touched and the display unit of the electronic device can be touch-inputted through the protection cover 10 in a situation in which an existing input by a finger (not shown) or a stylus pen (not shown) is impossible,

The above-described protection cover and the external case including the same are not limited to the above-mentioned embodiments and drawings, and it is apparent to those skilled in the art to which the present disclosure pertains that various substitutions, changes and modifications can be made without departing from the scope of the present disclosure.

It is intended that the present disclosure encompass such changes and modifications as fall within the scope of the appended claims.

What is claimed is:

1. A protection cover for protecting an electronic device, comprising:
a base; and
a conductor that fauns at least a portion of the base.

2. The protection cover of claim 1, wherein the conductor is located to be spaced apart from a display unit of the electronic device.

3. The protection cover of claim 1, wherein the base is formed of a transparent or semitransparent flexible film or plastic.

4. The protection cover of claim 1, wherein the conductor is applied, coupled, or attached to the base.

5. The protection cover of claim 1, wherein the base has at least one convex part, and the conductor is formed at a portion of the convex part facing the electronic device.

6. The protection cover of claim 1, wherein the base has at least one support.

7. The protection cover of claim 6, wherein the support is mounted or attached to a front surface of the electronic device.

8. The protection cover of claim 6, wherein the support is nonconductive and flexible.

9. The protection cover of claim 1, further comprising: a connection part connected to the protection cover and rotated through a hinge.

10. The protection cover of claim 9, wherein the connection part is disposed on at least one lateral surface of the electronic device.

11. An external case for protecting an electronic device, comprising:
a front cover having a protection cover; and
a rear cover connected to the front cover and disposed on a rear surface of the electronic device,
wherein the protection cover comprises a base; and a conductor that forms at least a portion of the base.

12. The external case of claim 11, wherein the protection cover is a transparent or semitransparent flexible film or plastic.

13. The external case of claim 11, wherein the conductor is configured to be spaced apart from the electronic device.

14. The external case of claim 11, wherein the protection cover has at least one support.

15. The external case of claim 14, wherein the support is mounted or attached to a front surface of the electronic device.

16. The external case of claim 14, wherein the support is nonconductive and flexible.

17. The external case of claim 11, wherein the protection cover is configured to be attached to or detached from the external case.

18. The external case of claim 11, wherein the protection cover further comprises a connection part connected to the protection cover and rotated through a hinge.

19. The external case of claim 11, wherein the connection part is disposed on at least one lateral surface of the external case.

20. The external case of claim 11, wherein the protection cover comprises an attaching portion to attach the protection cover to the external case.
